(19) United States
(12) Patent Application Publication
(10) Pub. No.: US 2006/0011469 A1
(43) Pub. Date: Jan. 19, 2006

(54) Coating system for coating a mold

(75) Inventor: Ga-Lane Chen, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD, Tu-cheng City (TW)

(21) Appl. No.: 11/176,043

(22) Filed: Jul. 7, 2005

(30) Foreign Application Priority Data
Jul. 16, 2004 (CN) 200410028185.3

(51) Int. Cl. C23C 14/00; C23C 14/32

(52) U.S. Cl. 204/192.12; 204/298.06; 204/298.07

(57) ABSTRACT

A coating system for coating a core insert includes a vacuum chamber (19) for providing a coating space, a pump system (10) for evacuating the vacuum chamber (19), a DC power supplier (18), a DC magnetron (14), and a gas-in system (16) for providing the vacuum chamber (19) a sputtering gas. The DC power supplier (18) has a negative end (181) and a positive end (182). The DC magnetron 14 is installed on one side of the vacuum chamber (19), and connects to the negative end (181) of the DC power supplier (18). Another kind of coating system includes, among other things, an RF power supplier (28) instead of a DC power supplier (18).

### FIELD OF THE INVENTION

The present invention generally relates to coating systems for coating molds, and more particularly to a system that can be used for coating, for example, a core insert of a mold.

### GENERAL BACKGROUND

Currently, digital camera modules are included as a feature in a wide variety of portable electronic devices. Most portable electronic devices are becoming progressively more miniaturized over time, and digital camera modules are correspondingly becoming smaller and smaller. Nevertheless, in spite of the small size of a contemporary digital camera module, consumers still demand excellent imaging. Image quality of a digital camera is mainly dependent upon the optical elements of the digital camera module.

Aspheric lenses are very important elements in the digital camera module. Mandy contemporary aspheric lenses are manufactured by way of glass molding. The glass molding process is generally performed under a high temperature and high pressure. Therefore, molds used in the molding process should have excellent chemical stability in order not to react with the glass material. In addition, the molds should also have enough rigidity and excellent mechanical strength in order not to be scratched. Furthermore, the molds should be impact-resistant at high temperatures and high pressures. Moreover, the molds should have excellent machinability, in order for them to be machined precisely and easily to form desired contours of the molded aspheric lenses. Finally, the molds must have a long working lifetime so that the cost of manufacturing aspheric lenses may be reduced.

A typical contemporary mold comprises a substrate and a protective film. The substrate is made of stainless steel, carborundum (SiC), or tungsten carbide (WC). The protective film is made of diamond-like carbon film (DLC), noble metals, or alloys of noble metals. The noble metals can be platinum (Pt), iridium (Ir), or ruthenium (Ru). The alloys of noble metals can be iridium-ruthenium (Ir—Ru), platinum-iridium (Pt—Ir), or iridium-rhenium (Ir—Re). The diamond-like carbon film is coated by a conventional sputtering system, and has a short working lifetime. The noble metals or alloys of noble metals have good chemical stability, rigidity and heat-resistance. Nevertheless, protective films made of noble metals or made of alloys of noble metals have poor adhesion with the substrate. Thus the mold coated by the conventional system generally has a short working lifetime, which escalates the cost of producing aspheric lenses.

What is needed is a coating system which is capable of forming a good durable protective film on a mold.

### SUMMARY

A system for coating a core insert comprises a vacuum chamber for providing a coating space, a pump system for evacuating the vacuum chamber, a DC power supplier, a DC magnetron, and a gas-in system for providing the vacuum chamber a sputtering gas. The DC power supplier has a negative end and a positive end. The DC magnetron is installed on one side of the vacuum chamber, and connects to the negative end of the DC power supplier.

Another system for coating a core insert comprises a vacuum chamber for providing a coating space, a pump system for evacuating the vacuum chamber, an RF power supplier, an RF (radio frequency) magnetron, and a gas-in system for providing the vacuum chamber a sputtering gas. The RF power supplier has two complementary power supply outputs. The RF magnetron is installed on one side of the vacuum chamber, and the RF magnetron connects to one of the two power supply outputs.

Other objects, advantages and novel features will become more apparent from the following detailed description when taken in conjunction with the accompanying drawings, in which:

### BRIEF DESCRIPTION OF THE DRAWINGS

FIG. 1 is a cross-sectional view of a female mold in accordance with a preferred embodiment of the present invention;

FIG. 2 is a schematic view of a coating system in accordance with a first preferred embodiment of the present invention; and

FIG. 3 is a schematic view of a coating system in accordance with a second preferred embodiment of the present invention.

### DETAILED DESCRIPTION OF PERFERRED EMBODIMENTS

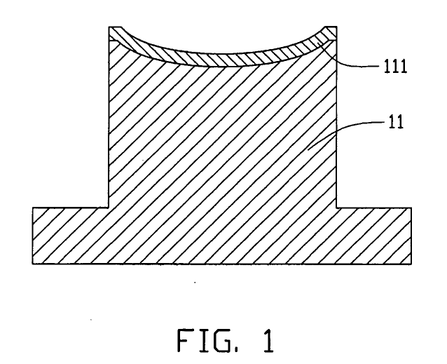

Referring to FIG. 1, in a preferred embodiment of the present invention, a female mold comprises a substrate 11 and a protective film 111. The protective film 111 is formed on a surface of the substrate 11. The substrate 111 is made of tungsten carbide (WC) material. The protective film 111 is made of a material selected from the group consisting of tungsten carbide (WC), carbon, a combination of carbon and tungsten carbide (C—WC), boron nitride carbide (BNC), cubic boron nitride (cBN), silicon nitride (Si₃N₄), carborundum (SiC), and zirconia-yttria (ZrO₂—Y₂O₃). In other exemplary embodiments, the protective film 111 may be formed on a surface of a male mold or a core insert, depending on the particular application.

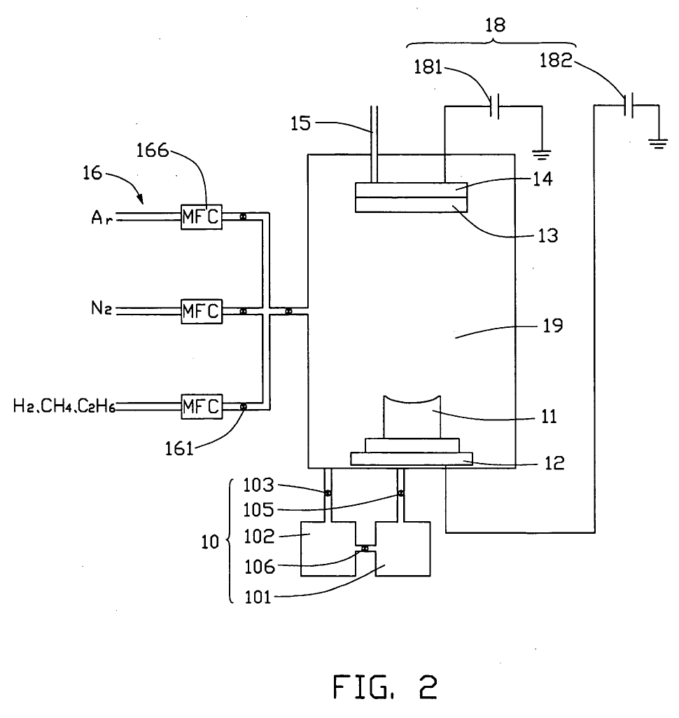

Referring to FIG. 2, in a first preferred embodiment of the present invention, a coating system for coating a female mold comprises a vacuum chamber 19 for providing a coating space, a pump system 10 for evacuating the vacuum chamber 19, a DC power supplier 18, a DC magnetron 14, and a gas supply system 16 for supplying a sputtering gas into the vacuum chamber 19. The DC power supplier 18 comprises a negative end 181 and a positive end 182. The DC magnetron 14 is disposed in an upper position in the vacuum chamber 19, and electrically connects to the negative end 181 of the DC power supplier 18. Further, the coating system comprises a target 13 assembled on the DC magnetron 14, a cooling system 15 arranged around the DC magnetron 14 and the target 13, and a base 12 for holding the substrate 11. The base 12 is disposed in a lower position in the vacuum chamber 19, opposite to the target 13. The base 12 is electrically connected to the positive end 182 of the DC power supplier 18. The target 13 is formed of a material selected from the group consisting of tungsten carbide (WC), carbon, a combination of carbon and tungsten carbide (C—WC), boron nitride carbide (BNC), and cubic boron nitride (cBN).

The pump system 10 includes a mechanical pump 101 and a turbopump 102. The mechanical pump 101 and the turbopump 102 are separately connected to the vacuum chamber 19 through a first valve 105 and a second valve 103 respectively. The mechanical pump 101 is connected to the turbopump 102 through a third valve 106. The gas supply system 16 comprises three mass flow controllers 166 and four gas valves 161. A gas, such as argon, a nitride gas, hydrogen, methane, or ethane, flows into the vacuum chamber 19 through a respective one of the mass flow controllers 166 and gas valves 161.

A method of coating a female mold by means of using the above-described coating system includes the steps of:
(1) disposing the substrate 11 on the base 13, and closing the vacuum chamber 19;
(2) opening the first valve 105, in order to preliminarily evacuate the vacuum chamber 19 with the mechanical pump 101;
(3) closing the first valve 105, and opening the second valve 103 and the third valve 106, in order to evacuate the vacuum chamber 19 until a pressure therein is lower than 2×10⁻⁶ torr by using the turbopump 102 and the mechanical pump 101;
(4) introducing a certain amount (e.g. at a flow rate of between 20-200 SCCM) of sputtering gas into the vacuum chamber 19 through the gas supply system 16;
(5) powering on the DC power supplier 18, in order to apply a bias voltage to the base 12 and the substrate 11, the bias voltage being in the range from −20 volts to −200 volts, and preferably being in the range from 40 volts to −150 volts;
(6) allowing the sputtering gas to be ionized into an ionized state, with a plasma being formed between the target 13 and the substrate 11, the ionized gas being accelerated by the DC magnetron 14 toward the target 13 to physically bombard the target 13 and dislodge atoms from the target 13, the atoms thereby escaping from the target 13 and depositing on the surface of the substrate 11, thus forming a protective film 111 (see FIG. 1) on the substrate 11;
(7) powering off the DC power supplier 18 and opening the vacuum chamber 19, thereby obtaining a female mold having a protective film 111 formed thereon.

In step (5), the cooling system 15 can be employed to cool the target.

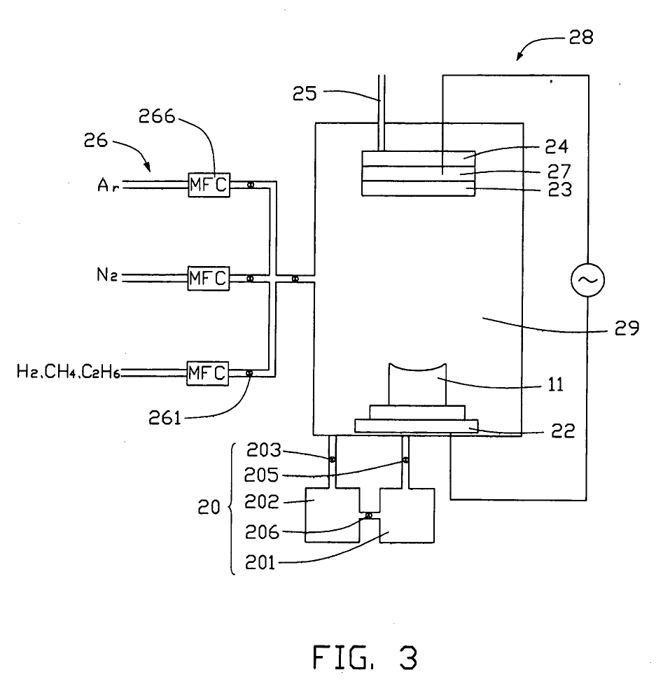

Referring to FIG. 3, in a second preferred embodiment of the present invention, a coating system for coating a female mold includes a vacuum chamber 29 for providing a coating space, a pump system 20 for evacuating the vacuum chamber 29, an radio frequency (RF) power supplier 28, an RF magnetron 24, and a gas supply system 26 for supplying a sputtering gas into the vacuum chamber 29. The RF magnetron 24 is disposed in an upper position in the vacuum chamber 29. Further, the coating system comprises a target 23 assembled on the RF magnetron 24, a cooling system 25 disposed around the RF magnetron 24 and the target 23, and a base 22 for holding the substrate 11. The base 22 is disposed in a lower position in the vacuum chamber 29, opposite from the target 23. The RF magnetron 24 and the base 22 are separately electrically connected to opposite electrodes of the RF power supplier 28. An operational frequency of the RF power supplier 28 is approximately 13.56 MHz. The target 23 is formed of a material selected from the group consisting of tungsten carbide (WC), carbon, a combination of carbon and tungsten carbide (C—WC), boron nitride carbide (BNC), cubic boron nitride (cBN), silicon nitride (Si₃N₄), carborundum (SiC), and zirconia-yttria (ZrO₂—Y₂O₃). A metal backing plate 27 is sandwiched between the target 23 and the RF magnetron 24, for transferring current to the target 23 if the target 23 is formed of an insulating material. The material of the backing plate 27 can be copper, or an alloy of copper and molybdenum.

The pump system 20 includes a mechanical pump 201 and a turbopump 202. The mechanical pump 201 and the turbopump 202 are separately connected to the vacuum chamber 29 through a first valve 205 and a second valve 203. The mechanical pump 201 is connected to the turbo pump 202 through a third valve 206. The gas supply system 26 includes three mass flow controllers 266 and four gas valves 261. A gas, such as argon, a nitride gas, hydrogen, methane, or ethane, flows into the vacuum chamber 29 through a respective one of the mass flow controllers 266 and gas valves 261.

A method of coating a female mold by means of using the above-described coating system includes the steps of:
(1) disposing the substrate 11 on the base 22, and closing the vacuum chamber 29;
(2) opening the first valve 205, in order to preliminarily evacuate the vacuum chamber 29 with the mechanical pump 201;
(3) closing the first valve 205, and opening the second valve 203 and the third valve 201, in order to evacuate the vacuum chamber 29 until a pressure therein is lower than 2×10⁻⁶ torr by using the turbopump 202 and the mechanical pump 201;
(4) introducing a certain amount (e.g. at a flow rate of between 20-200 SCCM) of sputtering gas into the vacuum chamber 29 through the gas supply system 26;
(5) powering on the RF power supplier 28, in order to supply electric power to the target 23 and the substrate 11, wherein a proportion of the electric power that is transferred to the target 23 is around 70%-98%, and a proportion of the electric power that is transferred to the substrate 11 is around 2%-30%;
(6) allowing the sputtering gas to be ionized into an ionized state, with a plasma being formed between the target 23 and the substrate 11, the ionized gas being accelerated by the RF magnetron 24 toward the target 23 to physically bombard the target 23 and dislodge atoms from the target 23, the atoms thereby escaping from the target 23 and depositing on the surface of the substrate 11, thus forming a protective film 111 (see FIG. 1) on the substrate 11;
(7) powering off the RF power supplier 28 and opening the vacuum chamber 29, thereby obtaining a female mold having a protective film 111 formed thereon.

In step (5), the cooling system 25 can be started for cooling the target.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A coating system for coating a mold, comprising:
a vacuum chamber for providing a coating space;
a pump system for evacuating the vacuum chamber;
a DC power supplier having a negative end and a positive end;
a sputtering cathode with a DC magnetron installed on one side of the vacuum chamber, the sputtering cathode electrically connecting to the negative end of the DC power supplier; and
a gas supply system for supplying a sputtering gas into the vacuum chamber.

2. The coating system as claimed in claim 1, wherein the pump system comprises a mechanical pump and a turbopump.

3. The coating system as claimed in claim 1, wherein the sputtering gas is at least one gas selected from the group consisting of argon, a nitride gas, hydrogen, methane, and ethane.

4. The coating system as claimed in claim 1, further comprising a sputtering target installed on the DC magnetron.

5. The coating system as claimed in claim 4, wherein the sputtering target is formed of a material selected from the group consisting of tungsten carbide (WC), carbon, a combination of carbon with tungsten carbide, boron nitride carbide (BNC), and cubic boron nitride (cBN).

6. The coating system as claimed in claim 1, further comprising a substrate disposed opposite to the sputtering cathode in the vacuum chamber.

7. The coating system as claimed in claim 6, further comprising a substrate holder for securing the substrate thereto.

8. The coating system as claimed in claim 7, wherein the substrate holder and the substrate are connected to the positive end of the DC power supplier, and the DC power supplier applies a bias voltage to the substrate.

9. The coating system as claimed in claim 8, wherein the bias voltage is in the range from −20 to −200 volts.

10. A coating system for coating a mold, comprising:
a vacuum chamber for providing a coating space;
a pump system for evacuating the vacuum chamber;
an RF (radio frequency) power supplier having two complementary power supply outputs;
a sputtering cathode with an RF magnetron installed on one side of the vacuum chamber, the RF magnetron being connected to one of the two power supply outputs; and
a gas supply system for supplying a sputtering gas into the vacuum chamber.

11. The coating system as claimed in claim 10, wherein the pump system comprises a mechanical pump and a turbopump.

12. The coating system as claimed in claim 10, wherein the sputtering gas is at least one gas selected from the group consisting of argon, a nitride gas, hydrogen, methane, and ethane.

13. The coating system as claimed in claim 10, wherein the coating system further comprises a sputtering target installed on the RF magnetron.

14. The coating system as claimed in claim 13, wherein a backing plate is sandwiched between the RF magnetron and the sputtering target.

15. The coating system as claimed in claim 13, wherein the sputtering target is a material selected from the group consisting of tungsten carbide (WC), carbon, a combination of carbon with tungsten carbide, boron nitride carbide (BNC), cubic boron nitride (cBN), silicon nitride (Si₃N₄), silicon carbide (SiC), and zirconia-yttria (ZrO₂—Y₂O₃).

16. The coating system as claimed in claim 10, further comprising a substrate disposed opposite to the sputtering cathode in the vacuum chamber.

17. The coating system as claimed in claim 16, wherein the substrate is secured by a substrate holder, and the substrate holder and the substrate are electrically connected to one of the two power supply outputs, and the RF power supplier applies a bias voltage to the substrate.

18. The coating system as claimed in claim 17, wherein a proportion of the electric power that is transferred to the substrate is around 2%-30% of the total electric power output from the RF power supplier.

19. The coating system as claimed in claim 10, wherein an operational frequency of the RF power supplier is approximately 13.56 MHz.

20. A method to arrange a system for coating a substrate, comprising the steps of:
preparing a chamber capable of being vacuumed by a pump system;
positioning said substrate in said chamber;
placing a coating target in said chamber spacing from said positioned substrate;
electrically connecting said substrate and said coating target respectively with a power supplier capable of removing and coating parts of said coating target onto said substrate by applying power on said substrate and said coating target; and
supplying said vacuumed chamber with a sputtering gas so as to contribute to electrical transmission between said spaced substrate and coating target for achieving said coating of said parts of said coating target onto said substrate.
